(19) United States
(12) Patent Application Publication
(10) Pub. No.: US 2008/0000667 A1
(43) Pub. Date: Jan. 3, 2008

(54) Apparatus and method for shielding a gas sensor

(76) Inventors: Paul H. Ruterbusch, Flushing, MI (US); Charles Scott Nelson, Fenton, MI (US)

Correspondence Address: DELPHI TECHNOLOGIES, INC., M/C 480-410-202, PO BOX 5052, TROY, MI, 48007, US

(21) Appl. No.: 11/455,599

(22) Filed: Jun. 19, 2006

(51) Int. Cl. H05K 7/20

(52) U.S. Cl. 174/16.1

(57) ABSTRACT

A shield assembly for a gas sensor and a method for securing the shield assembly to the gas sensor are provided. The shield assembly includes an outer shield and an inner shield. The outer shield includes an outer wall defining a cavity therein and a tip portion located at one end of the outer wall. The outer wall includes a plurality of apertures extending therethrough. The inner shield is disposed within the cavity of the outer shield. The inner shield includes an inner-wall defining an inner cavity therein. The inner wall is in a facing spaced relationship with respect to the outer wall. The inner shield further includes an engagement portion, a tip engaging portion, and a plurality of inner shield apertures. The plurality of inner shield apertures and the plurality of apertures of the outer wall provide fluid communication to the inner cavity through the outer shield and the inner shield. The inner shield is wedged between the outer shield and a portion of the gas sensor when the engagement portion engages the portion of the gas sensor and the tip engagement portion makes contact with the tip portion.

### TECHNICAL FIELD

The present invention relates to an apparatus and method for shielding a gas sensor.

### BACKGROUND

An oxygen gas sensor is typically disposed within a vehicle engine exhaust gas stream for qualitative and quantitative analysis of the exhaust gases. A casing is typically secured to the oxygen gas sensor and configured for protecting a sensing member of the oxygen gas sensor. The casing is further configured so a sufficient amount of the exhaust gases is allowed to flow into an interior region of the casing in order to contact the sensing member for analysis of the exhaust gases. In some applications, the casing is a dual casing design wherein an inner casing is disposed within an outer casing and a portion of the inner casing is welded to a portion of the outer casing to secure the two casings together. A disadvantage with this configuration is that the welded area degrades and the inner casing becomes loose within the outer casing due to vibration forces encountered by the dual casing.

Accordingly, it is desirable to provide a dual casing design for use with an oxygen gas sensor wherein an inner casing is secured within an outer casing so the inner casing does not loosen due to vibration forces encountered during testing and or use of the oxygen gas sensor.

### SUMMARY OF THE INVENTION

A shield assembly for a gas sensor in accordance with an exemplary embodiment is provided. The shield assembly includes an outer shield and an inner shield. The outer shield includes an outer wall defining a cavity therein and a tip portion located at one end of the outer wall. The outer wall includes a plurality of apertures extending therethrough. The inner shield is disposed within the cavity of the outer shield. The inner shield includes an inner wall defining an inner cavity therein. The inner wall is in a facing spaced relationship with respect to the outer wall. The inner shield further includes an engagement portion, a tip engaging portion, and a plurality of inner shield apertures. The plurality of inner shield apertures and the plurality of apertures of the outer wall provide fluid communication to the inner cavity through the outer shield and the inner shield. The inner shield is wedged between the outer shield and a portion of the gas sensor when the engagement portion engages the portion of the gas sensor and the tip engagement portion makes contact with the tip portion.

A gas sensor in accordance with another exemplary embodiment is provided. The gas sensor includes an outer shell, a sensing member extending from the outer shell, and a shield assembly for protecting the sensing member. The shield assembly includes an outer shield and an inner shield. The outer shield includes an outer wall defining a cavity therein and a tip portion located at one end of the outer wall. The outer wall includes a plurality of apertures extending therethrough. The inner shield is disposed within the cavity of the outer shield. The inner shield includes an inner wall defining an inner cavity therein. The inner wall is in a facing spaced relationship with respect to the outer wall. The inner shield further includes an engagement portion, a tip engaging portion, and a plurality of inner shield apertures. The plurality of inner shield apertures and the plurality of apertures of the outer wall provide fluid communication to the inner cavity through the outer shield and the inner shield. The engagement portion of the inner shield makes contact with a portion of the outer shell when a flange portion of the outer shield is secured to another portion of the outer shell wherein the inner shield is fixedly secured to the outer shield and the tip engagement portion makes contact with the tip portion.

A method for securing a shield assembly to a gas sensor in accordance with another exemplary embodiment is provided. The method includes securing an inner shield within an outer shield of the shield assembly. An engagement portion of the inner shield engages an inner surface of the outer shield wherein an inner wall of the inner shield is in a facing spaced relationship with respect to the inner surface. The method further includes securing the shield assembly to an outer shell of the gas sensor wherein a portion of the outer shield is secured to the outer shell and the engagement portion of the inner shield also engages another portion of the shell.

A shield assembly for a gas sensor in accordance with another exemplary embodiment is provided. The shield assembly includes an outer shield and an inner shield. The outer shield includes an outer wall defining a cavity therein and a tip portion located at one end of the outer wall. The outer wall includes a first plurality of apertures extending therethrough. The inner shield is disposed within the cavity of the outer shield. The inner shield includes an inner wall, an engagement portion, and a tip engaging portion. The engagement portion is disposed at a first end of the inner wall. The tip engaging portion is disposed at a second end of the inner wall. The inner wall defines an inner cavity therein and includes a second plurality of apertures extending therethrough. The inner wall is in a facing spaced relationship with respect to the outer wall. The first and second plurality of apertures provide fluid communication to the inner cavity through the outer shield and the inner shield. The inner shield is wedged between the outer shield and a portion of the gas sensor when the engagement portion of the inner shield engages the portion of the gas sensor and the tip engaging portion of the inner shield contacts the tip portion of the outer wall.

A shield assembly for a gas sensor in accordance with another exemplary embodiment is provided. The shield assembly includes an outer shield and an inner shield. The outer shield includes an outer wall defining a cavity therein and a tip portion located at one end of the outer wall. The outer wall includes a plurality of apertures extending therethrough. The inner shield is disposed within the cavity of the outer shield. The inner shield includes an inner wall, a first plurality of tab members and a second plurality of tab members, and a tip engaging portion. The first plurality of tab members are disposed at a first plurality of locations around a periphery of the inner wall at a first end of the inner wall. The first plurality of tab members are configured to contact a portion of the gas sensor. The second plurality of tab members are disposed at a second plurality of locations around the periphery of the inner wall at the first end of the inner wall. The second plurality of tab members are configured to contact the outer wall. The tip engaging portion is disposed at a second end of the inner wall. The first and second plurality of tab members define a plurality of openings therebetween. The plurality of apertures and the plurality of openings provide fluid communication to the inner cavity through the outer shield and the inner shield. The inner shield is wedged between the outer shield and the portion of the gas sensor when the first plurality of tab members of the inner shield engages the portion of the gas sensor and the tip engaging portion of the inner shield contacts the tip portion of the outer wall.

### BRIEF DESCRIPTION OF THE DRAWINGS

FIG. 1 is a perspective view of a shield assembly in accordance with an exemplary embodiment of the present invention;

FIG. 2 is a view along lines 2-2 of FIG. 1;

FIG. 3 is a perspective view of a gas sensor assembly having a shield assembly in accordance with an exemplary embodiment;

FIG. 4 is a view along lines 4-4 of FIG. 3;

FIGS. 5-10 are partial cross sectional views of various alternative exemplary embodiments of the present invention;

FIG. 11 is a perspective view of an inner shield constructed in accordance with another alternative exemplary embodiment of the present invention;

FIG. 12 is a partial cross sectional view of a gas sensor and shield assembly constructed in accordance with another alternative exemplary embodiment of the present invention;

FIG. 13 is a perspective view of an inner shield constructed in accordance with still another alternative exemplary embodiment of the present invention;

FIG. 14 is a partial cross sectional view of a gas sensor and shield assembly constructed in accordance with still another alternative exemplary embodiment of the present invention;

FIGS. 15 and 16 are partial cross sectional views illustrating a tooling apparatus for use with exemplary embodiments of the present invention; and

FIGS. 17-25 are partial cross sectional views of various alternative exemplary embodiments of the present invention.

### DETAILED DESCRIPTION OF EXEMPLARY EMBODIMENTS

In accordance with an exemplary embodiment of the present invention, a shield assembly is disposed about a portion of a sensing element or member of an oxygen gas sensor. The shield assembly is configured to protect the sensing member from contaminates and allow exhaust gases from the exhaust gas stream to flow into the shield assembly to contact the sensing member for analysis of the exhaust gases. The shield assembly is a dual shield design wherein an inner shield is disposed within an outer shield.

In an exemplary embodiment, the inner shield and the outer shield are configured so that a portion of the inner shield is wedged between a portion of the outer shield and a portion of the gas sensor when the shield assembly is secured to the gas sensor. An advantage to this configuration is that the inner shield is secured at more than one location within the outer shield. Securing the inner shield at more than one location reduces a probability of the inner shield loosening or dislodging from the outer shield. In particular, exemplary embodiments of the present invention provide a shield assembly wherein the inner shield assembly is less likely to be dislodged when compared to an inner shield having only a single weld or point of securement to the outer shield. Additionally, securing the inner shield at more than one location will reduce the stress levels encountered by a single securement feature. Further, securing the inner shield at more than one location within the outer shield may simplify manufacturing the shield assembly. For example, securing the inner shield to the outer shield at two locations will reduce stress applied to welds applied to secure the shield portions together and may negate the need for a weld altogether.

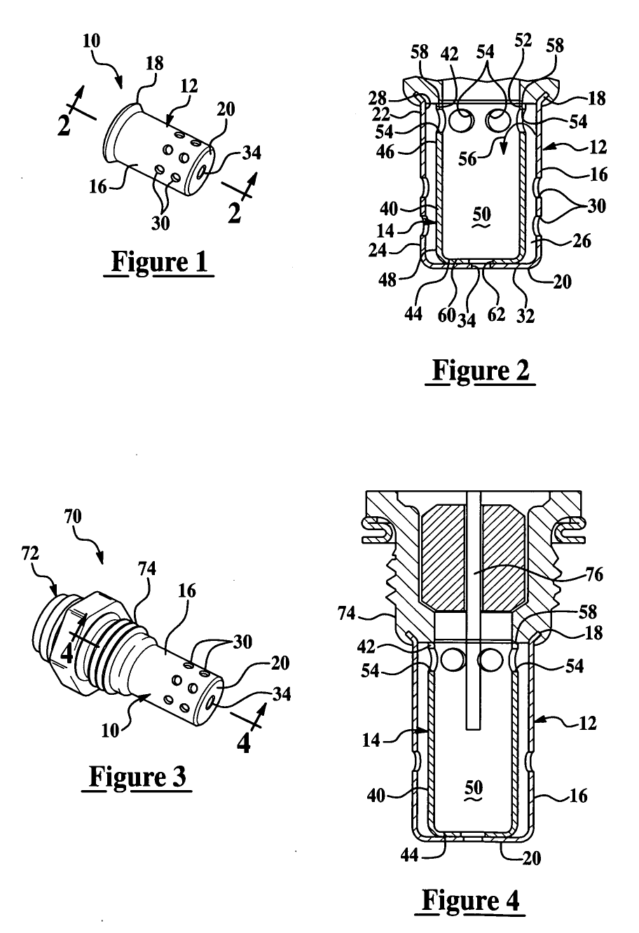

Referring now to FIGS. 1 and 2, a shield assembly 10 in accordance with an exemplary embodiment of the present invention is illustrated. As illustrated, shield assembly 10 comprises an outer shield 12 and an inner shield 14 wherein the inner shield is disposed within outer shield 12. In an exemplary embodiment, outer shield 12 includes an outer wall 16, a flange member 18, and a tip portion 20. Outer wall 16 extends from a first end 22 to a second end 24 of the outer shield. The outer wall and tip portion 20 define a cavity 26 therein. Cavity 26 is configured to receive inner shield 14 therein. First end 22 of outer wall 16 defines an aperture or opening 28. Aperture 28 is configured to allow inner shield 14 to be received therethrough into cavity 26.

Outer wall 16 also includes a plurality of apertures 30 spaced around a periphery of the outer wall and extending therethrough proximate second end 24. The plurality of apertures will allow exhaust gases from an exhaust gas stream to flow into cavity 26. In an alternative exemplary embodiment, outer wall 16 may have an arrangement of apertures other than those illustrated in FIG. 1 so that exhaust gases from the exhaust gas stream can flow into cavity 26.

Flange member 18 extends in an outwardly direction away from first end 22 of outer wall 16 in order to provide a means for securing outer shield 12 to a shell portion of the gas sensor. In an exemplary embodiment, flange member 18 is secured to the shell portion of the gas sensor via any suitable attachment process. For example, flange member 18 is secured to the shell portion by a cold forming process wherein a portion of the shell member is overmolded or pushed onto flange member 18 wherein flange member 18 is surrounded and secured to a portion of an outer shell of a gas sensor. As will be discussed herein, the inner shield is wedged between the shell portion of the gas sensor and another portion of the outer shield during this securement step.

Tip portion 20 is defined by a wall portion 32. The wall portion is disposed across the second end of the outer wall and includes an aperture or opening 34. Aperture 34 provides fluid communication to cavity 26.

In an exemplary embodiment, inner shield 14 includes an inner wall 40, an engagement portion 42 and a tip engaging portion 44. Inner shield 14 is configured to be disposed within cavity 26 of outer shield 12 wherein inner wall 40 is spaced apart from outer wall 16 of the outer shield. Inner shield 14 is further configured to receive a portion of the sensing member of the gas sensor therein. Inner wall 40 extends from a first end 46 to a second end 48 of the inner shield. Inner wall 40 and the tip engaging portion 44 define a cavity 50 for receiving the sensing member therein. First end 46 of inner wall 40 defines an opening 52 that is configured to allow the sensing member to be received into cavity 50. Inner wall 40 also includes a plurality of apertures 54 spaced around a periphery of the inner wall. In one non-limiting exemplary embodiment, the apertures are located proximate to first end 46. Plurality of apertures 54 are configured to allow fluid communication of exhaust gases from cavity 26 of the outer shield into cavity 50 of the inner shield along a flow path 56. In an alternative exemplary embodiment the plurality of apertures 54 are positioned in another portion of the inner shield.

In accordance with an exemplary embodiment, engagement portion 42 is utilized to wedge the inner shield between the shell portion of the gas sensor and a portion of the outer shield when the outer shield is secured to the shell portion. In one exemplary embodiment, engagement portion 42 comprises a portion of inner wall 40 that extends toward the shell portion of the gas sensor when the shield assembly is secured to the gas sensor. In an exemplary embodiment, inner shield 14 is configured so that a surface or edge 58 of engagement portion 42 abuts against a surface of the shell portion when the outer shield is secured to the shell portion of the gas sensor. The outer shield is configured so portion tip engaging portion 44 is forced against tip portion 20 when edge 58 abuts against the surface of the shell portion.

In an exemplary embodiment, tip engaging portion 44 is defined by a wall portion 60 that extends from second end 48 of inner wall 40. In addition, an aperture or opening 62 is disposed in wall portion 60. Aperture 62 provides fluid communication to cavity 50 through aperture 34 of the outer shield.

In an exemplary embodiment, the inner shield and the outer shield are substantially tubular shaped members wherein the inner shield is smaller than the outer shield and a portion of the inner shield is spaced apart from a portion of the outer shield to allow fluid communication of exhaust gases from the cavity of the outer shield into the cavity of the inner shield. Of course, other non-tubular configurations are contemplated to be within the scope of exemplary embodiments of the present invention. Non-limiting materials contemplated for the shield assembly are “300” and “400” series high-temperature stainless steel and equivalents thereof.

Referring now to FIGS. 3 and 4, a gas sensor 70 is illustrated in accordance with an exemplary embodiment of the present invention. Gas sensor 70 includes a sensing device 72 and shield assembly 10 secured thereto. Gas sensing device 72 includes an outer shell 74 and an exhaust gas sensing member 76 disposed therein. A portion of sensing member 76 extends outwardly from outer shell 74 into cavity 50 of inner shield 14 when the shield assembly is secured thereto. Flange member 18 is secured to outer shell 74, thereby securing shield assembly 10 to gas sensing device 72. When flange member 18 is secured to outer shell 74, surface 58 of engagement portion 42 of inner shield 14 abuts against outer shell 74 to wedge the inner shield between the outer shell and tip portion 20 of outer shield 12, thereby securely holding the inner shield at two locations within the outer shield. It is contemplated that a plurality of alternative configurations are possible for wedging the inner shield within the outer shield of the shield assembly when the outer shield is secured to the outer shell of the gas sensor.

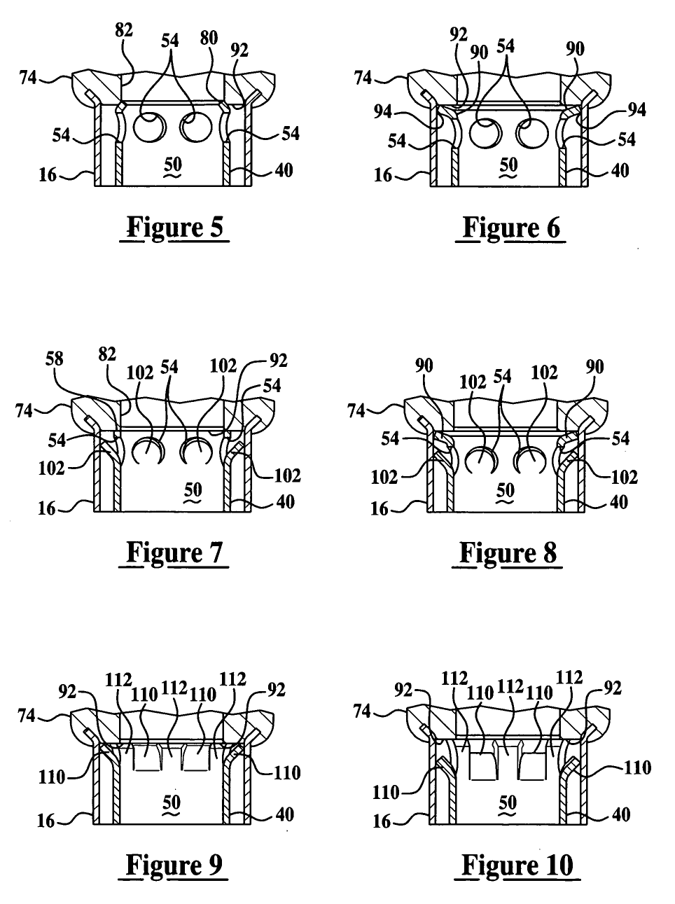

Referring to FIGS. 5-10, various embodiments for securing the inner shield 14 to outer shell 74 are illustrated. As illustrated in each of the embodiments, only a portion of the shield assembly is shown and it is contemplated that the inner shield is wedged between the outer shell and a portion of the outer shield. The sensing member of the gas sensor disposed in the cavity of the inner shield (as shown in FIG. 4) is omitted from FIGS. 5-10 to more clearly illustrate a region of the inner shield proximate the outer shell of the gas sensor.

In one exemplary embodiment, the inner shield is configured so that an engagement portion of the inner shield is compressed against the outer shell of the gas sensor when the shield assembly is secured to the outer shell, to wedge the inner shield between the outer shell and a portion of the outer shield. In another exemplary embodiment, an engagement portion of the inner shield is deflected from its original position by the outer shell of the gas sensor when the shield assembly is secured to the gas sensor. In this embodiment, the material of the inner shield has resilient characteristics so that the engagement portion is biased back towards its un-deflected position in order to secure the inner shield to the outer shield when the shield assembly is secured to the outer shell.

In another exemplary embodiment, the inner shield includes a plurality of tabs that extend in a direction away from the cavity of the inner shield toward an inner surface of the outer shield. In this embodiment, the inner shield is retained within the outer shield due to contact between a surface or edge of each of the plurality of tabs and an inner surface of the outer shield. In another alternative exemplary embodiment, the inner shield is configured to be disposed into the cavity of the outer shield, wherein the plurality of tabs slidably engage the inner surface of the outer shield as the inner shield is inserted therein. In yet another exemplary embodiment, the engagement portion of the inner shield includes a first surface configured to make contact with the outer shell when the inner shield is wedged between the outer shell and the outer shield and a second surface of the engagement portion makes contact with a portion of the gas sensor.

Referring now to FIG. 5, the engagement portion of the inner shield is configured to have a chamfered surface 80, which depends inwardly from an adjoining portion of the inner wall of the inner shield in a direction toward the outer shell of the gas sensor. As illustrated, chamfered surface 80 is configured to be received within an opening 82 of the outer shell. Accordingly, when the shield assembly is secured to the outer shell of the gas sensor a portion of the chamfered surface is received within opening 82 and the tip engagement portion (not shown) makes contact with the outer shield. In addition, the material of the inner shield has resilient characteristics wherein the chamfered surface is provided with a biasing force after it is deflected slightly inward through the engagement of chamfered surface 80 and opening 82.

Referring now to FIG. 6, another alternative exemplary embodiment of the present invention is illustrated. The engagement portion of the inner shield is configured to have a curved portion or flange 90 that depends outwardly away from the opening into cavity 50 of inner shield 14. As illustrated, curved portion 90 extends away from the opening in an arcuate manner. In this embodiment, the curved portion 90 is deflected outwardly when a contact surface 92 of a portion of the outer shell makes contact with curved portion 90 as shield assembly 10 is secured to outer shell 74. During this securement step, the curved portion will deflect outwardly until an end portion 94 abuts against an inner surface of the outer shell. In addition and as illustrated, surface 92 will also provide a binding force against curved portion 90 when shield assembly 10 is secured to the outer shell.

Referring now to FIG. 7, another alternative exemplary embodiment of the present invention is illustrated. The engagement portion abuts against the contact surface of the outer shell. Openings or apertures 54 are defined by a plurality of tab members 102, which comprise a portion of the inner wall that is removed or stamped therefrom. For example, apertures 54 are formed by a stamping process wherein the tab members remain secured to a portion of aperture 54 and depend outwardly from the inner wall of the inner shield. In this embodiment, tab members are configured to frictionally engage the inner surface of the outer shield when the inner shield is inserted therein thereby providing a means for locating and fixedly securing the inner shield to the outer shield. Thereafter, end portion 58 of the engagement portion will make contact with contact surface 92 when the shield assembly is secured to the outer shell.

Referring now to FIG. 8, the engagement portion of the inner shield is configured to have a curved portion 90 as described and shown in FIG. 6 while also having tab members 102 as shown and described in FIGS. 7 and 8.

Referring now to FIGS. 9 and 10, another alternative exemplary embodiment is illustrated. The engagement portion is configured to have a plurality of tab members extending outwardly from the periphery of the opening of cavity 50. In this embodiment, the tab members are configured in an alternating arrangement wherein a first portion 110 of the plurality of tab members is configured to make contact with an inner surface of the outer shield while a second portion 112 of the plurality of tab members is configured to make contact with contact surface 92 of the outer shell of the gas sensor. In these embodiments the apertures for fluid communication with cavity 50 are defined by the alternating arrangement of the first portion and the second portion of the plurality of tab members. In the FIG. 10 embodiment, the first portion of the plurality of tab members are configured to have a shorter length than the first portion of the plurality of tab members illustrated in FIG. 9 thus, providing a larger opening between each of the plurality of tab members. As in the previous embodiments, the first portion of the plurality of tab members is configured to engage the inner surface of the outer shield when the inner shield is inserted therein and the second portion of the plurality of tab members make contact with contact surface 92 when the shield assembly is secured to the outer shell of the gas sensor.

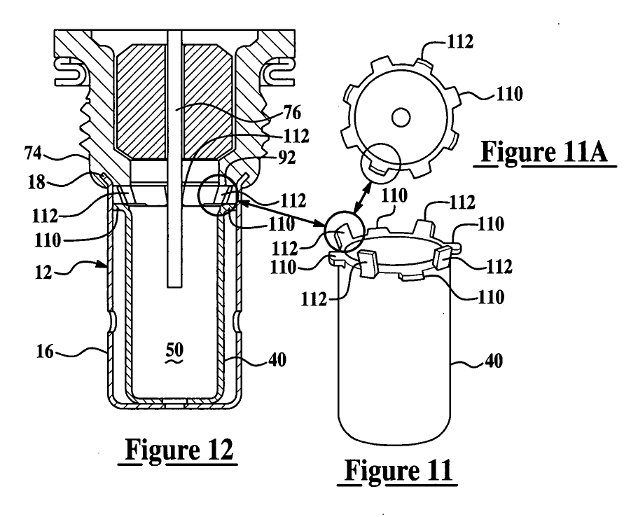

Referring now to FIGS. 11-14, another alternative exemplary embodiment of the present invention is illustrated. Here, the plurality of tab members are spaced apart from each other to define a gap or opening therebetween when the inner shield is secured to the outer shield and in order to provide fluid communication into cavity 50. In this embodiment, the first portion of the plurality of tab members depend laterally away from the periphery of the opening of cavity 50 while the second portion of the plurality of tab members depend angularly away from the periphery of the opening of cavity 50. As in the previous embodiments, the first portion of the plurality of tab members are configured to engage the inner surface of the outer shield when the inner shield is inserted therein wherein they provide a locating and securement feature and the second portion of the plurality of tab members make contact with contact surface 92 when the shield assembly is secured to the outer shell of the gas sensor. As such, the first portion and the second portion of the plurality of tab members provide a more robust means for securing the inner shield to the outer shield.

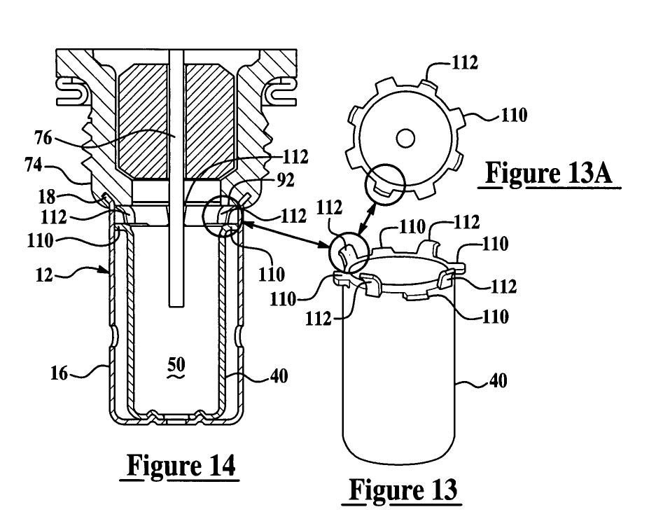

Referring now to FIGS. 13 and 14, another alternative exemplary embodiment of the present invention is illustrated. Here and as in the previous embodiment, the plurality of tab members are spaced apart from each other to define a gap or opening therebetween when the inner shield is secured to the outer shield and in order to provide fluid communication into cavity 50. However, the second portion of the plurality of tab members are also configured to have a varying angular configuration as they depend away from the periphery of the opening into cavity 50.

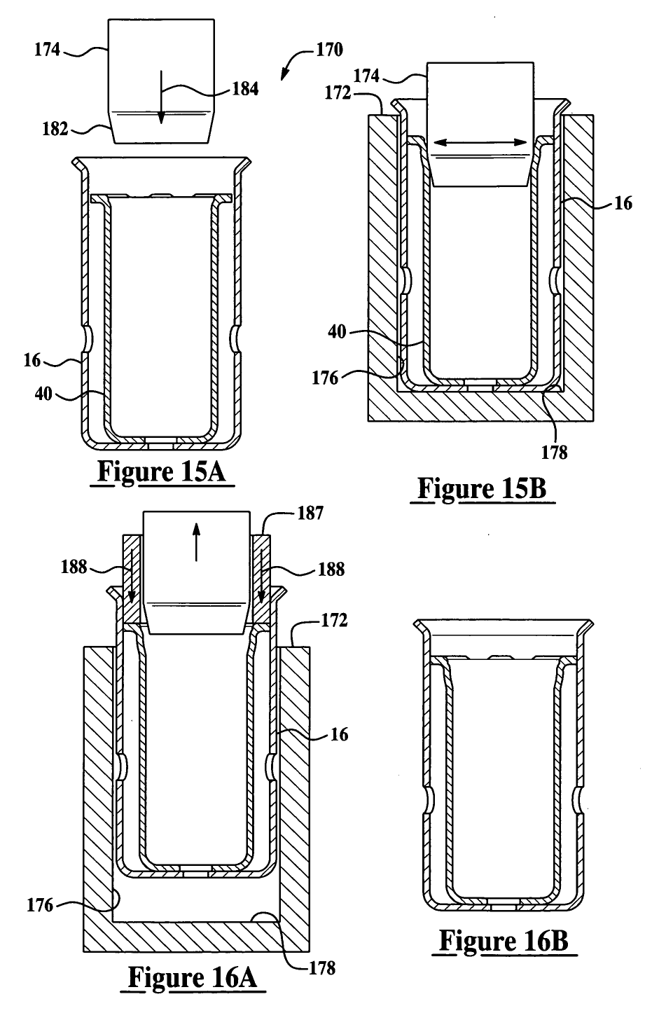

Referring now to FIGS. 15 and 16, a method for securing the inner shield to the outer shield in accordance with an exemplary embodiment will now be described. A tooling apparatus 170 is used to ensure that the tab members engage the inner surface of the outer shield as it is desirable for each of the tabs configured to have contact with the outer shield to actually make contact with the outer shield in order to secure and locate the inner shield within the outer shield. In accordance with an exemplary embodiment it is understood that tooling apparatus 170 can be configured for use with any of the configurations of inner shield 14 as illustrated in FIGS. 6-14.

As illustrated, tooling apparatus 170 includes a holding fixture 172 and an expansion tool 174. Holding fixture 172 is provided for supporting the outer shield 12 when expansion tool 174 is being used to eliminate the spaces between the tabs and the inner surface of the outer wall. Holding fixture 172 includes inner surfaces 176 and 178 defining a cavity therein. Inner surface 176 is configured to snugly receive an outer periphery of outer wall 16 of outer shield 12 while inner surface 178 is configured to support outer shield 12 disposed within the holding fixture when the tip engaging portion of inner shield contacts the tip portion of the outer shield.

Expansion tool 174 is provided to move a portion of the inner shield outwardly so that a surface of each of the plurality of tabs configured for making contact with the outer shield is pressed against the inner surface of the outer shield and thereby substantially eliminate any space between a contact surface of each of these tabs and the inner surface of the outer wall. In accordance with an exemplary embodiment, the expansion tool moves the inner shield such that each of the plurality of tabs configured for making contact with the outer shield remains in contact with the outer shield after the shield assembly is removed from the holding fixture and the expansion tool is removed from the inner shield. As illustrated, expansion tool 174 comprises a chamfered engagement portion 182. Engagement portion 182 is configured such that when expansion tool 174 moves in the direction of arrow 184 portion 182 urges a portion of the inner shield outwardly wherein the tabs are urged against the inner surface of the outer shield.

Referring now to FIG. 16A, removal of the expansion tool from the cavity of the inner shield will now be described. In order to remove the expansion tool from the cavity of the inner shield after the inner shield has been expanded outwardly, a support member 187 is used to maintain each of the tabs making contact with the outer shield in a substantially fixed position while the expansion tool is removed from the cavity of inner shield. In operation, a force is applied to support member 187 in the direction 188 while expansion tool 174 is removed from the cavity of the inner shield.

In accordance with exemplary embodiments of the present invention, the inner shield is also secured to another portion of the outer shield. For example and in one exemplary embodiment, the tip engaging portion of the inner shield is secured to the tip portion of the outer shield by a welding operation. It should be noted that a stress level and cracks in the weld securing the tip engaging portion to the tip portion may be reduced due to the engagement portion making contact with the inner wall of the outer shield and a portion of the outer shell of the gas sensor. In alternative exemplary embodiments, the weld of the tip portion to the tip engaging portion is replaced or supplemented by other forms of securement, which increase the tolerance of the weld between the shield portions or otherwise simplify manufacture of the shield assembly.

For example, other methods include utilizing a common fastener or an adhesive for securing the two shield portions together at a position remote from the engagement portion of the inner shield. In another exemplary embodiment, the tip engaging portion engages the tip portion via a protrusion that engages an aperture in one of the shields. In another exemplary embodiment, a surface of the tip engaging portion engages a surface of the tip portion and/or a surface of the outer wall of the outer shield so that the inner shield is securely fastened to the outer shield. In another exemplary embodiment, the tip engaging portion engages the tip portion wherein one of the portions includes a protrusion that engages an indentation of the other portion. In yet another exemplary embodiment, the tip engaging portion may engage the tip portion by using a combination of any of the aforementioned embodiments. Depending on the configuration of the shield assembly, inner and outer shield portions other than the tip engaging portion and the tip portion may be used in the securement of the inner shield to the outer shield.

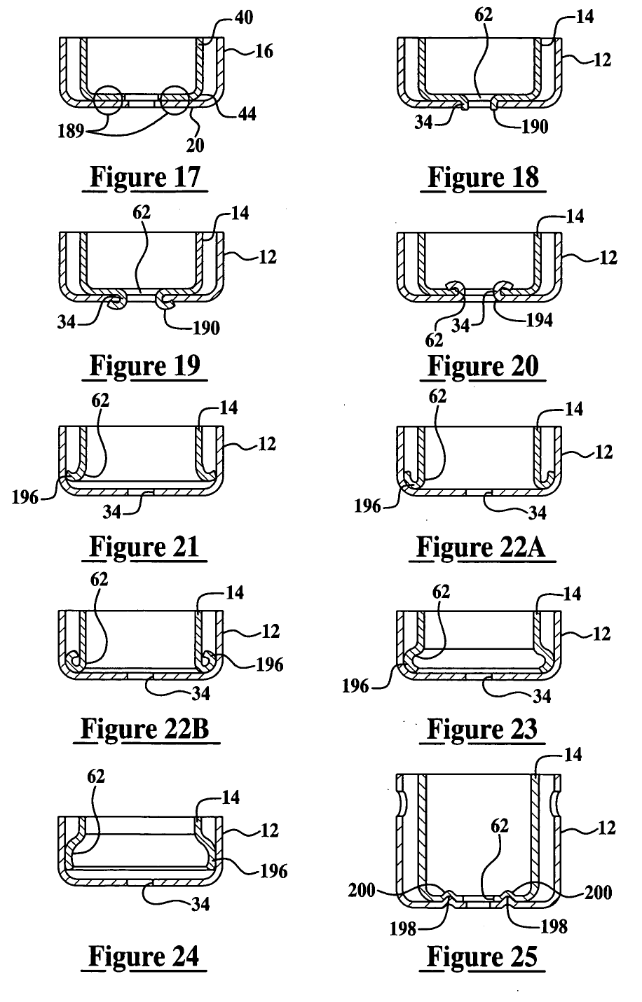

Referring now to FIGS. 17-25, various exemplary embodiments for securing the tip engaging portion of the inner shield to the tip portion of the outer shield are illustrated. For purposes of clarity, the apertures 30 illustrated in FIGS. 1-4 are omitted from FIGS. 17-25 to more clearly illustrate securement of the tip engaging portion and the tip portion of the shield assembly.

Referring now to FIG. 17 and in accordance with an exemplary embodiment, tip engaging portion 44 is secured to tip portion 20 via a welding operation, such as a spot welding operation along a circumferential area 189. As described above the locating and securement features of the various embodiments of the engagement portion of the inner shield will locate the inner shield within the outer shield prior to the welding operation. Moreover, the engaging portion will reduce the stress applied to the welds thus, extending the life expectancy of the same as the shield assembly of the gas sensor is exposed to environments wherein the shield assembly is subjected to vibrations and other forces, which may weaken welds that are not supplemented with engagement portions of exemplary embodiments of the present invention.

Referring now to FIG. 18 and in an alternative exemplary embodiment, opening 62 of the tip engaging portion is configured to have an annular wall portion 190 configured to be received within opening 34. Wall portion 190 is configured to frictionally engage opening 34 in order to secure inner shield 14 to outer shield 12. Alternatively, referring to FIG. 19, wall portion 190 is configured to have a height or length greater than the thickness of the material defining opening 34 in the outer shield so that a portion of the wall portion may be folded over onto an exterior surface of the outer shield. In another alternative exemplary embodiment as illustrated in FIG. 20, the tip portion of the outer shield is configured to have a wall portion 194 that defines opening 34 and extends into opening 62 wherein a portion of the wall portion is folded over onto an inner surface of the inner shield to fixedly secure the two together.

In yet another alternative exemplary embodiment and referring now to FIGS. 21-24, opening 62 of inner shield 14 is substantially larger than opening 34 of the outer shield and a peripheral edge 196 of opening 62 is configured to frictionally engage or make an interference fit with an inner surface of outer shield 12. For example, peripheral edge 196 may comprise a curved flange portion, a beveled opening or other configuration to engage an inner surface of the outer shield in order to fixedly secure the inner and outer shields together in conjunction with any of the numerous embodiments contemplated for engaging a portion of the outer shell of the gas sensor and another inner surface of the outer shield.

Referring now to FIG. 25, another alternative exemplary embodiment is illustrated. The outer shield is configured to have a single protrusion or a plurality of protrusions 198 for engaging a complimentary feature or features 200 in a corresponding surface of the inner shield. Protrusion or protrusions 198 and feature or features 200 are configured to engage one another as well as limit lateral movement of the inner shield within the outer shield. In another alternative exemplary embodiment, the protrusion 198 and features 200 are used to position the inner shield within the outer shield. In one exemplary embodiment, protrusion 198 and corresponding feature 200 is defined by a ring shaped groove positioned a surface of the inner and outer shields.

The exemplary embodiments disclosed herein provide a shield assembly for a gas sensor wherein an inner shield is securely held within an outer shield by wedging the inner shield between a portion of the gas sensor and another portion of the outer shield, thereby reducing a likelihood the inner shield will loosen within the outer shield during use of the gas sensor.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the present application.

1. A shield assembly for a gas sensor, the shield assembly comprising:
an outer shield having an outer wall defining a cavity therein and a tip portion located at one end of the outer wall, the outer wall having a plurality of apertures extending therethrough;
an inner shield disposed within the cavity of the outer shield, the inner shield having an inner wall defining an inner cavity therein, the inner wall being in a facing spaced relationship with respect to the outer wall, the inner shield further comprising an engagement portion, a tip engaging portion, and a plurality of inner shield apertures, the plurality of inner shield apertures and the plurality of apertures of the outer wall provide fluid communication to the inner cavity through the outer shield and the inner shield; and
wherein the inner shield is wedged between the outer shield and a portion of the gas sensor when the engagement portion engages the portion of the gas sensor and the tip engagement portion makes contact with the tip portion.

2. The shield assembly as in claim 1, wherein the tip portion further comprises an aperture and the tip engaging portion comprises an aperture aligned with the aperture of the tip portion and the engagement portion of the inner shield has a chamfered surface configured to engage an opening in the gas sensor.

3. The shield assembly as in claim 1, wherein the engagement portion of the inner shield comprises a flange portion depending outwardly from a periphery of the inner wall, the flange portion being configured to frictionally engage a portion of an inner surface of the outer wall thereby securing the inner shield within the outer shield.

4. The shield assembly as in claim 1, wherein each of the plurality of inner shield apertures has a tab member depending therefrom, wherein each tab member is configured to frictionally engage a portion of an inner surface of the outer wall thereby securing the inner shield within the outer shield.

5. The shield assembly as in claim 4, wherein the engagement portion of the inner shield comprises a flange portion depending outwardly from a periphery of the inner wall, the flange portion being configured to frictionally engage another portion of an inner surface of the outer wall.

6. The shield assembly as in claim 1, wherein the engagement portion of the inner shield further comprises a plurality of tabs depending away from a periphery of the inner wall, wherein a first portion of the plurality of tabs are configured to engage an inner surface of the outer shield and a second portion of the plurality of tabs are configured to engage the portion of the gas sensor.

7. The shield assembly as in claim 6, wherein the first portion and the second portion of the plurality of tabs are arranged in an alternating fashion.

8. The shield assembly as in claim 7, wherein the first portion and the second portion of the plurality of tabs are laterally spaced apart from each other along the periphery of the inner wall.

9. The shield assembly as in claim 8, wherein each of the inner shield apertures are disposed between one of the first portion of the plurality of tabs and one of the second portion of the plurality of tabs.

10. The shield assembly as in claim 1, wherein the tip portion further comprises an aperture and the tip engaging portion comprises an aperture aligned with the aperture of the tip portion and the tip engaging portion of the inner shield is secured to the tip portion of the outer shield via a weld and wherein the engagement portion of the inner shield comprises a plurality of tabs depending away from a periphery of the inner wall, wherein a first portion of the plurality of tabs are configured to engage an inner surface of the outer shield and a second portion of the plurality of tabs are configured to engage the portion of the gas sensor.

11. The shield assembly as in claim 10, wherein the first portion and the second portion of the plurality of tabs are arranged in an alternating fashion and the first portion and the second portion of the plurality of tabs are laterally spaced apart from each other along the periphery of the inner wall and each of the inner shield apertures are disposed between one of the first portion of the plurality of tabs and one of the second portion of the plurality of tabs.

12. The shield assembly as in claim 1, wherein the tip engaging portion of the inner shield is not welded to the tip portion of the outer shield.

13. The shield assembly as in claim 1, wherein the tip engaging portion of the inner shield further comprises an aperture defined by a wall member depending therefrom, the wall member configured to be received within an aperture of the tip portion.

14. The shield assembly as in claim 1, wherein the tip portion of the outer shield further comprises an aperture defined by a protrusion depending therefrom, the protrusion configured to be received within an aperture of the tip engaging portion.

15. The shield assembly as in claim 1, wherein the tip portion further comprises an aperture and the tip engaging portion comprises an aperture substantially larger than the aperture of the tip portion, wherein a peripheral edge of the aperture of the inner shield is configured to frictionally engage an inner surface of the outer shield securing the inner shield within the outer shield.

16. The shield assembly as in claim 1, wherein the inner and outer shields of the shield assembly comprise a stainless steel material.

17. A gas sensor, comprising:
an outer shell;
a sensing member extending from the outer shell; and
a shield assembly for protecting the sensing member, the shield assembly comprising:
an outer shield having an outer wall defining a cavity therein and a tip portion located at one end of the outer wall, the outer wall having a plurality of apertures extending therethrough;
an inner shield disposed within the cavity of the outer shield, the inner shield having an inner wall defining an inner cavity therein, the inner wall being in a facing spaced relationship with respect to the outer wall, the inner shield further comprising an engagement portion, a tip engaging portion, and a plurality of inner shield apertures, the plurality of inner shield apertures and the plurality of apertures of the outer wall provide fluid communication to the inner cavity through the outer shield and the inner shield; and
wherein the engagement portion of the inner shield makes contact with a portion of the outer shell when a flange portion of the outer shield is secured to another portion of the outer shell wherein the inner shield is fixedly secured to the outer shield and the tip engagement portion makes contact with the tip portion.

18. The gas sensor as in claim 17, wherein the tip portion further comprises an aperture and the tip engaging portion comprises an aperture aligned with the aperture of the tip portion and the engagement portion of the inner shield has a chamfered surface configured to engage an opening in the gas sensor.

19. The gas sensor as in claim 17, wherein the engagement portion of the inner shield comprises a flange portion depending outwardly from a periphery of the inner wall, the flange portion being configured to frictionally engage a portion of an inner surface of the outer wall thereby securing the inner shield within the outer shield.

20. The gas sensor as in claim 17, wherein each of the plurality of inner shield apertures has a tab member depending therefrom, wherein each tab member is configured to frictionally engage a portion of an inner surface of the outer wall and wherein the engagement portion of the inner shield further comprises a flange portion depending outwardly from a periphery of the inner wall, the flange portion being configured to frictionally engage another portion of an inner surface of the outer wall.

21. The gas sensor as in claim 20, wherein the tip engaging portion of the inner shield further comprises an aperture defined by a wall member depending therefrom, the wall member configured to be received within an aperture of the tip portion.

22. The gas sensor as in claim 20, wherein the tip portion further comprises an aperture and the tip engaging portion comprises an aperture substantially larger than the aperture of the tip portion, wherein a peripheral edge of the aperture of the inner shield is configured to frictionally engage an inner surface of the outer shield securing the inner shield within the outer shield.

23. A method for securing a shield assembly to a gas sensor, the method comprising:
securing an inner shield within an outer shield of the shield assembly, wherein an engagement portion of the inner shield engages an inner surface of the outer shield, wherein an inner wall of the inner shield is in a facing spaced relationship with respect to the inner surface; and
securing the shield assembly to an outer shell of the gas sensor wherein a portion of the outer shield is secured to the outer shell and the engagement portion of the inner shield also engages another portion of the outer shell.

24. The method as in claim 23, wherein the inner shield further comprises an aperture defined by a wall member depending therefrom, the wall member configured to be received within an aperture of a tip portion of the outer shield.

25. The method as in claim 23, wherein the outer shield further comprises a tip portion and the inner shield further comprises a tip engaging portion, wherein the tip portion further comprises an aperture and the tip engaging portion comprises an aperture substantially larger than the aperture of the tip portion, wherein a peripheral edge of the aperture of the inner shield is configured to frictionally engage an inner surface of the outer shield securing the inner shield within the outer shield.

26. A shield assembly for a gas sensor, comprising:
an outer shield having an outer wall defining a cavity therein and a tip portion located at one end of the outer wall, the outer wall having a first plurality of apertures extending therethrough;
an inner shield disposed within the cavity of the outer shield, the inner shield having an inner wall, an engagement portion, a tip engaging portion, the engagement portion disposed at a first end of the inner wall, the tip engaging portion disposed at a second end of the inner wall, the inner wall defining an inner cavity therein and having a second plurality of apertures extending therethrough, the inner wall being in a facing spaced relationship with respect to the outer wall, the first and second plurality of apertures providing fluid communication to the inner cavity through the outer shield and the inner shield; and
wherein the inner shield is wedged between the outer shield and a portion of the gas sensor when the engagement portion of the inner shield engages the portion of the gas sensor and the tip engaging portion of the inner shield contacts the tip portion of the outer wall.

27. A shield assembly for a gas sensor, comprising:
an outer shield having an outer wall defining a cavity therein and a tip portion located at one end of the outer wall, the outer wall having a plurality of apertures extending therethrough;
an inner shield disposed within the cavity of the outer shield, the inner shield having an inner wall, a first plurality of tab members and a second plurality of tab members, and a tip engaging portion, the first plurality of tab members are disposed at a first plurality of locations around a periphery of the inner wall at a first end of the inner wall, the first plurality of tab members are configured to contact a portion of the gas sensor, the second plurality of tab members are disposed at a second plurality of locations around the periphery of the inner wall at the first end of the inner wall, the second plurality of tab members are configured to contact the outer wall, the tip engaging portion disposed at a second end of the inner wall, the first and second plurality of tab members defining a plurality of openings therebetween, the plurality of apertures and the plurality of openings providing fluid communication to the inner cavity through the outer shield and the inner shield; and
wherein the inner shield is wedged between the outer shield and the portion of the gas sensor when the first plurality of tab members of the inner shield engages the portion of the gas sensor and the tip engaging portion of the inner shield contacts the tip portion of the outer wall.
